(19) United States
(12) Patent Application Publication
(10) Pub. No.: US 2006/0002197 A1
(43) Pub. Date: Jan. 5, 2006

(54) Method and apparatus to detect invalid data in a nonvolatile memory following a loss of power

(76) Inventor: John C. Rudelic, Folsom, CA (US)

Correspondence Address: INTEL CORPORATION, P.O. BOX 5326, SANTA CLARA, CA, 95056-5326, US

(21) Appl. No.: 10/882,379

(22) Filed: Jun. 30, 2004

(51) Int. Cl. G11C 16/04

(52) U.S. Cl. 365/189.09

(57) ABSTRACT

Briefly, in accordance with an embodiment of the invention, a method and apparatus to detect invalid data in a memory is provided. The method may include setting at least one power loss recovery (PLR) status bit in response to the writing to or erasing of a plurality of nonvolatile memory cells of a nonvolatile memory, wherein the at least one PLR status bit indicates whether the writing to or erasing of the plurality of memory cells was interrupted by a loss of power and wherein the setting of the at least one PLR status bit is performed by the nonvolatile memory. Other embodiments are described and claimed.

### BACKGROUND

Nonvolatile memories such as, for example, a flash electrically erasable programmable read-only memory (“flash EEPROM” or “flash memory”) may retain their data until the memory is erased. Electrical erasure of the flash memory may include erasing the contents of the memory of the device in one relatively rapid operation. The flash memory may then be programmed with new data or code.

The unexpected loss of power during the writing or erasing of a flash memory may create invalid or corrupt data in the flash memory if the write or erase operations were not completed when power was lost. If no indication is provided that the erase or write operation was not completed, then the invalid data may be assumed by a user or a software program using the data to be valid. This may result in undesirable consequences.

Thus, there is a continuing need for alternate ways to detect invalid data in a nonvolatile memory.

### BRIEF DESCRIPTION OF THE DRAWINGS

The subject matter regarded as the invention is particularly pointed out and distinctly claimed in the concluding portion of the specification. The -present invention, however, both as to organization and method of operation, together with objects, features, and advantages thereof, may best be understood by reference to the following detailed description when read with the accompanying drawings in which:

FIG. 1 is a block diagram illustrating a portion of a computing system in accordance with an embodiment of the present invention;

FIG. 2 is a flow diagram illustrating a method in accordance with an embodiment of the present invention;

FIG. 3 is a diagram illustrating the setting of a power loss recovery (PLR) status bit relative to time in accordance with an embodiment of the present invention;

FIG. 4 is a flow diagram illustrating a method in accordance with an embodiment of the present invention;

FIG. 5 is a diagram illustrating the setting of two power loss recovery (PLR) status bits relative to time in accordance with an embodiment of the present invention; and

FIG. 6 is a block diagram illustrating a wireless device in accordance with an embodiment of the present invention.

It will be appreciated that for simplicity and clarity of illustration, elements illustrated in the figures have not necessarily been drawn to scale. For example, the dimensions of some of the elements are exaggerated relative to other elements for clarity. Further, where considered appropriate, reference numerals have been repeated among the figures to indicate corresponding or analogous elements.

### DETAILED DESCRIPTION

In the following detailed description, numerous specific details are set forth in order to provide a thorough understanding of the present invention. However, it will be understood by those skilled in the art that the present invention may be practiced without these specific details. In other instances, well-known methods, procedures, components and circuits have not been described in detail so as not to obscure the present invention.

In the following description and claims, the terms “include” and “comprise,” along with their derivatives, may be used, and are intended to be treated as synonyms for each other. In addition, in the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

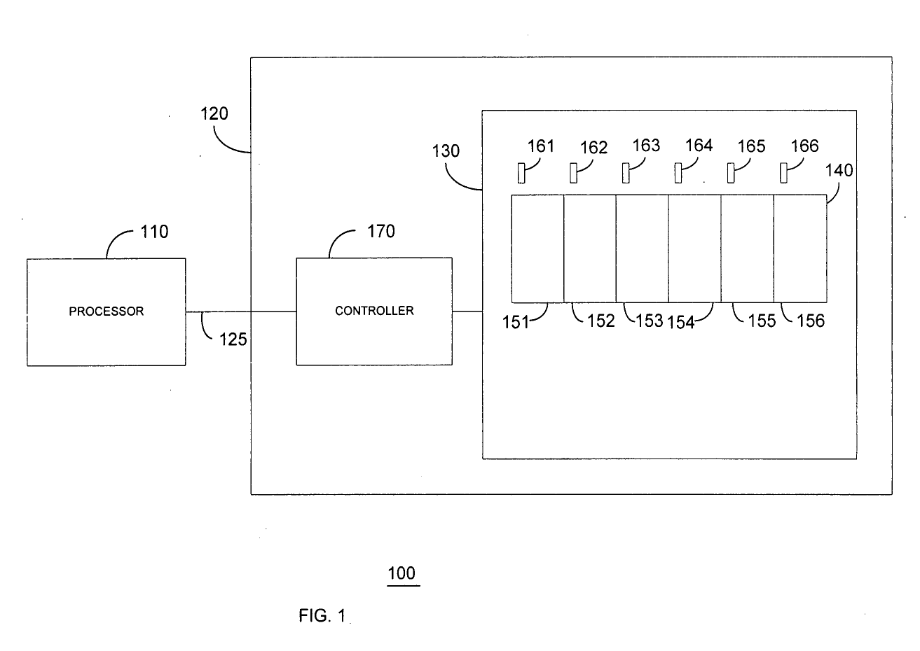

FIG. 1 is a block diagram illustrating a portion of a computing system 100 in accordance with an embodiment of the present invention. Although the scope of the present invention is not limited in this respect, system 100 may be used in a personal digital assistant (PDA), a wireless telephone (e.g., cordless or cellular phone), a pager, a digital music player, a laptop or desktop computer, a set-top box, a printer, etc.

System 100 may include a processor 110 and a nonvolatile memory 120 coupled to processor 110 via a bus 125. Although not shown, system 100 may include other components such as, for example, more processors, input/output (I/O) devices, memory devices, or storage devices. However, for simplicity these additional components have not been shown.

In one embodiment, processor 110 may be a discrete component and external to nonvolatile memory 120. Processor 110 may include digital logic to execute software instructions and may also be referred to as a central processing unit (CPU). Software instructions executed by processor 110 may be stored in nonvolatile memory 120 and may also be referred to as code. Although not shown, processor 110 may include a CPU core that may comprise an arithmetic-logic unit (ALU) and registers. Bus 125 may include one or more busses and may be a single 16-bit bus in one embodiment.

Nonvolatile memory 120 may be a NAND or NOR type of flash memory, and may be a single bit per cell or multiple bits per cell memory. Nonvolatile memory 120 may comprise one or more chips or integrated circuits (ICs). Although nonvolatile memory 120 is discussed as a flash memory, this is not a limitation of the present invention. In other embodiments, nonvolatile memory 120 may be another type of memory capable of storing data when power is removed from the memory. For example, nonvolatile memory 120 may be a ferroelectric random access memory (FRAM), a magnetic random access memory (MRAM), a disk memory such as, for example, an electromechanical hard disk, an optical disk, a magnetic disk, or any other nonvolatile device capable of storing code and/or data.

The term “information” may be used to refer to data, instructions, or code. Examples of data may include a serial number of a device or-encryption keys. If system 100 is used in a wireless telephone, examples of data may include ring tone data or telephone number data. Examples of code may include a software application (e.g., a downloadable computer game), an operating system (O/S), a java applet, or libraries used by the operating system.

Nonvolatile memory 120 may store both code and data and may store code in one partition of memory 120 and may store data in another partition of memory 120. Each partition of nonvolatile memory 120 may comprise a plurality of blocks of memory, wherein each block includes a plurality of memory cells capable of storing at least one bit of information. The partition of nonvolatile memory 120 where data is stored may include one or more blocks and may be referred to as the data volume of nonvolatile memory 120. The partition of nonvolatile memory 120 where code is stored may include one or more blocks and may be referred to as the code volume of nonvolatile memory 120.

A code manager may be used to store and manage the code, e.g., code objects, in the code volume of nonvolatile memory 120. The code manager may store code contiguously in the code volume of nonvolatile memory 120 so that it can be directly accessed from nonvolatile memory 120, i.e., fetched and executed from nonvolatile memory 120 without the intermediate step of loading the code to a volatile random access memory (RAM). This is sometimes referred to as execute-in-place (XIP) in some flash memories. By storing code contiguously in nonvolatile memory 120, pointer access may be provided so that processor 110 may directly access code stored in array 130.

Similarly, a data manager may be used- to store and manage data in the data volume of nonvolatile memory 120. The data manager may be software or code, such as filesystem software, flash management software, or an application programming interface (API),and may be stored in the code volume of nonvolatile memory 120. The data manager may be executed by processor 110 which may be external to nonvolatile memory 120. In one embodiment, data need not be stored contiguously in the data volume, and may be stored in fragments.

In one embodiment, memory 120 may include 128 blocks and a block of memory may range in size from about 64 kilobytes (Kbytes) to about 256 Kbytes. A block may be subdivided into colonies, wherein a colony may include a plurality of nonvolatile memory cells and ranges in size from about 512 bytes to about one kilobyte. A colony may be a unit of memory and may also be referred to as a sector.

Nonvolatile memory 120 may include a memory array 130 that may include a plurality of blocks. In one embodiment, array 130 includes a block 140. Block 140 may be subdivided into a plurality of colonies 151-156, wherein each colony includes a plurality of nonvolatile memory cells (not shown), e.g., flash memory cells. Array 130 may further include a plurality of power loss recover (PLR) status cells 161-166, wherein each status cell is associated with, or corresponds to one colony. For example, status cells 161-166 respectively correspond to colonies 151-156.

In one embodiment, each status cell may be a single nonvolatile memory cell, e.g., a flash memory cell, that is used to store a power loss recovery (PLR) status bit. The PLR status bit may be set after the completion of a write operation or an erase operation, and therefore, the PLR status bit may be used to indicate that a write or erase operation completed successfully.

Nonvolatile memory 120 may also include hardware and/or software that may be used to perform a power loss recovery (PLR) operation that may be used to detect invalid or unreliable data in memory 120. For example, nonvolatile memory 120 may include a controller 170 that may include circuitry, e.g., digital logic, and may execute code (e.g., microcode or firmware) that may be used to perform PLR functions. Controller 170 may be used to perform various control activities for memory 120. For example, in addition to PLR operations, controller 170 may also be used to perform writing, erasing, and reading operations in memory 120 in response to write, erase, or read commands from a processor external to memory 120, e.g., processor 110.

The PLR operation may also be referred to as a PLR function or a PLR mechanism. Controller 170 may also be referred to as a control circuit and in various embodiments maybe a state machine, an application specific integrated circuit (ASIC), or a processor such as, e.g., a microprocessor, co-processor, or a microcontroller.

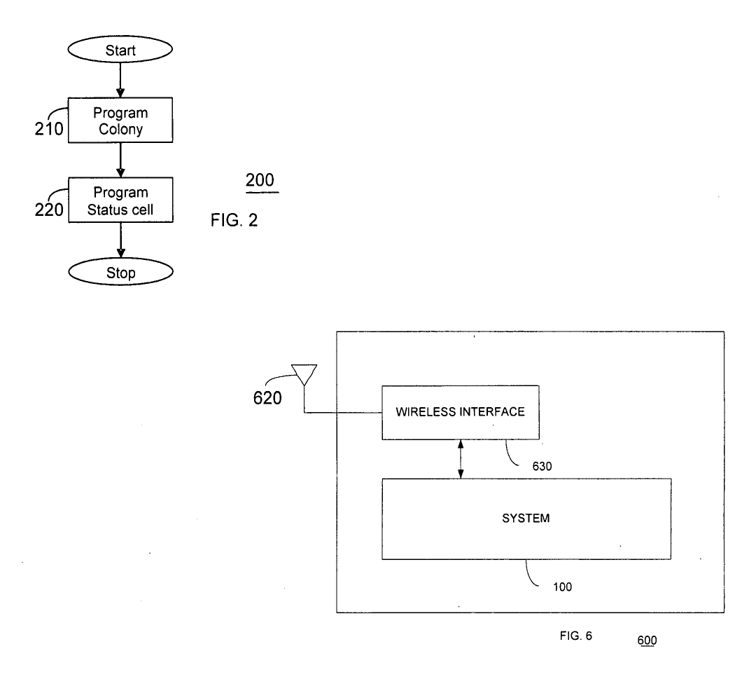

Turning to FIG. 2, what is shown is a flow diagram illustrating a method 200 to set a PLR status bit in accordance with an embodiment of the present invention. This method will be described with reference to system 100 of FIG. 1.

Method 200 may begin with programming a colony (block 210). This may include memory 120 receiving a write command from processor 110 to write data to colony 153 in block 140. After the data is written to colony 153, a corresponding status bit stored in the corresponding status cell 163 may be set, e.g., to a logic 0, to indicate that the write operation completed successfully. In other words, following the programming of colony 153, a PLR operation may include programming of the corresponding status cell 163 (block 220). Any colony of memory 120 that has programmed data without a programmed PLR status bit may be considered unreliable.

The setting of the PLR status bits or programming of PLR status cells 161-166 may be performed by controller 170 of memory 120 rather than by code executing on a processor external to memory 120 such as, for example, flash management software executed by processor 110. In other words, the setting of the PLR status bit may be performed by internal resources of nonvolatile memory 120 as part of an erase or write operation. That is, no specific PLR set status bit command from processor 110 is used to set the PLR status bit.

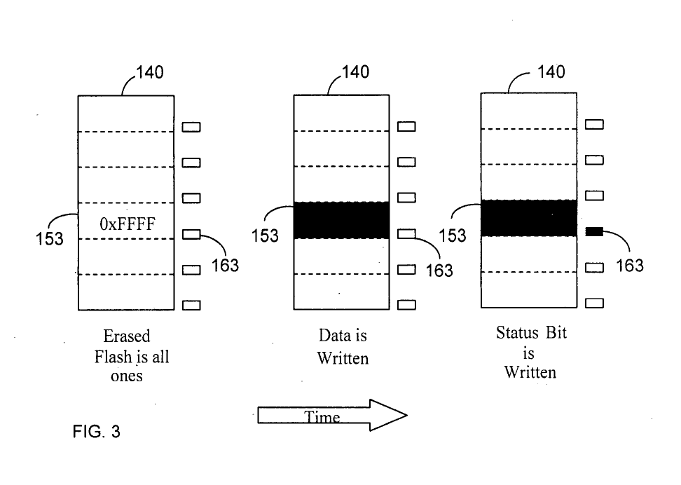

Turning to FIG. 3, shown is a diagram illustrating the setting of a PLR status bit as part of a power loss recovery (PLR) operation in accordance with an embodiment of the present invention. The diagram of FIG. 3 illustrates the programming or writing of data to a colony 153 of memory 120 relative to time. As is illustrated, initially colony 153 is erased to all logic ones. Then, data is written to colony 153, which is illustrated by shading in the portion representing colony 153, and finally the corresponding status cell 163 is written to indicate that the write operation to colony 153 is completed, which is illustrated by shading in the portion representing status cell 163.

In one embodiment, if a PLR status bit is not set, and one or more memory cells in the corresponding colony contain programmed or non-erased information indicating that a write operation was at least begun to this colony, then the information stored in this colony may be deemed unreliable, invalid, or corrupt. For example, if array 130 is a flash memory array and if the memory state convention is that an erase state means that all the memory cells of a block in the flash memory array store a logic 1, then, hardware and/or software in flash memory 120 may be used to implement a PLR operation that includes determining if one or more of the memory cells of a colony include a logic 0 and then determining if the corresponding PLR status bit is set. If programmed data exists in a colony and the corresponding PLR status bit is not set, then the data stored may be deemed to be unreliable. The data may be unreliable due to an unexpected power loss during the erasing or writing of data to that colony.

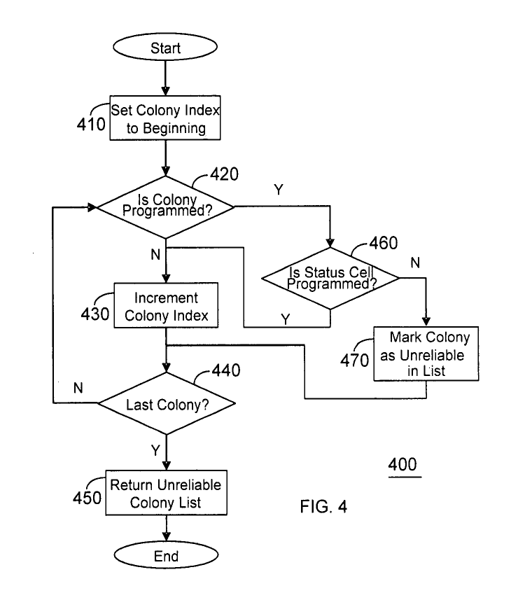

FIG. 4 is a flow diagram illustrating a method 400 to determine or detect whether invalid data exists in nonvolatile memory 120 due to an unexpected loss of power in accordance with an embodiment of the present invention. Method 400 will be described with reference to system 100 of FIG. 1. In addition, method 400 may be performed upon initialization or power-up of memory 120 or may be done prior to, or as part of a read operation to read data in memory 120.

Method 400 may begin with setting a colony index to a beginning point (block 410). This colony index may be maintained in controller 170. Next, it is determined whether a colony at the colony index is programmed (diamond 420). If the colony is not programmed, e.g., the colony is in an erased state, then controller 170 may increment the colony index (block 430) and determine if the colony at the colony index is the last colony to be examined (diamond 440). If it is determined that it is the last colony, then a final unreliable colony list that includes a list of colonies having invalid data may be returned to a device external to memory 120 (e.g., processor 110) or stored in nonvolatile memory 120 (block 450). In one embodiment, an address of a colony having unreliable or invalid data may be stored in memory 120 and/or sent to processor 110. As an example, processor 120 may receive the address of the colony having invalid data from memory 120 during or after initialization of memory 120. Alternatively, the PLR status cells of memory 120 may be readable by processor 110 and processor 110 may execute code to determine if the PLR status bit is set. If it is not the last colony, then the colony at the incremented colony index is examined to determine if that colony is programmed (block 420).

If it is determined that the colony at the current colony index is programmed (block 420), then it is determined if the corresponding status cell is programmed (block 460), e.g., if the PLR status bit in the corresponding status cell is set. If the corresponding PLR status bit is set or programmed, then the data may be deemed to be reliable or valid and the colony index may be incremented (block 430). If the corresponding PLR status bit is not set or programmed, then the colony at the current colony index is marked as unreliable by controller 170 using, for example, a list (block 470) that may be stored in memory 120 as discussed above.

It is noted that the methods and apparatuses discussed above may be used in both single bit per cell or multiple bit per cell memories. In addition, in an alternate embodiment, more than one PLR status bit may be used to implement a power loss recovery (PLR) operation wherein the plurality of PLR status bits may be set by memory 120, e.g., the plurality of PLR status bits may be set by controller 170. In one embodiment, two PLR status bits may be used to implement a PLR operation.

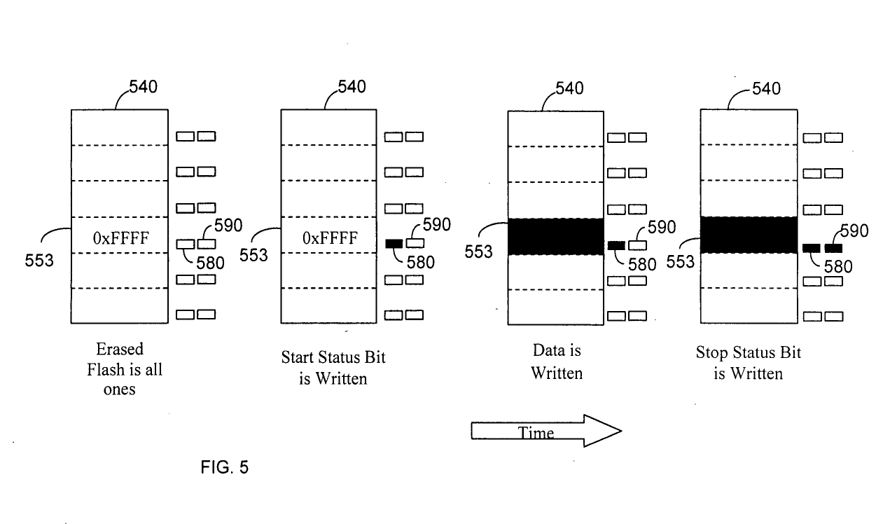

FIG. 5 is a diagram illustrating the setting of two PLR status bits as part of a power loss recovery (PLR) operation in accordance with an embodiment of the present invention. The diagram of FIG. 5 illustrates the programming or writing of data to a colony 553 relative to time. Colony 553 may be part of a memory block 540 within nonvolatile memory 120 (FIG. 1). Two PLR status cells 580 and 590 may be used to store the two PLR status bits. These cells may be linked to the colony that is being written to or erased to denote if a write operation or erase operation to that colony is completed successfully, e.g., not interrupted by a power loss. In this example, PLR status cells 580 and 590 may be linked to colony 553. PLR status cell 580 may be used to store a PLR start status bit that my be set just prior to writing information to colony 553 and PLR status cell 690 may be used to store a PLR stop status bit that may be set just after writing information to colony 553.

As is illustrated, in one example, initially colony 553 is erased to all logic ones and neither of the PLR status bits in cells 580 or 590 are set. Next, the corresponding PLR start status bit that is stored in PLR status cell 580 is set, which is illustrated by shading in the portion representing cell 580. Then, data is written to colony 553, which is illustrated by shading in the portion representing colony 553, and finally the corresponding PLR stop status bit that is stored in status cell 590 is set to indicate that the write operation to colony 553 is completed, which is illustrated by shading in the portion representing status cell 590.

In one embodiment, without any request from a device external to memory 120, controller 170 of memory 120 sets the PLR start and stop status bits as part of, or in response to a write or erase operation. A similar algorithm as to the one discussed with reference to FIG. 4 may be used upon power-up or prior to a read operation to determine whether a colony has invalid data by using the information stored in the linked status cells.

Compared to an implementation that uses at least two PLR status bits, in the embodiment wherein one PLR status bit is used, performance of a system may be improved by reducing the number of write operations used to program or erase the nonvolatile memory since only one PLR status bit may need to be set for each write or erase operation.

As discussed above, methods and apparatuses are disclosed that include using resources internal to the nonvolatile memory device to perform power loss tracking, e.g., to set PLR status bits, using the hardware of the memory compared to using flash management software that is being executed external to the nonvolatile memory.

In one embodiment, each colony may have a status bit associated with it. Data may be stored in a nonvolatile memory in either single-bit-per-cell or multi-level-cell modes. The status bit may signal that a colony program operation has completed successfully. The order of operations may be 1) program the flash colony and 2) program the colony status bit. In this scenario, any flash colony that has programmed data without a programmed status bit may be considered unreliable.

Upon power up or initialization of the nonvolatile memory, the memory may be scanned looking for any colony that has programmed data without a programmed status bit. Recovery from an unreliable colony may be handled by the filesystem software and may differ based on the architecture of the filesystem software.

Compared to an implementation wherein the power loss recovery bits may be set by software executed by a processor external to nonvolatile memory 120, it may be advantageous to set the power loss recovery bit using hardware and/or software resources in memory 120 as discussed above since using resources in memory 120 to set the PLR status bit(s) may increase performance since it may be faster, i.e., require less time, to set the PLR status bit(s) using hardware in memory 120 compared to using a processor external to memory 120. In addition, implementing the PLR using memory hardware may reduce issues with software vendors' as they transition their products to newer memory devices, since the software vendors may not have to rework software significantly to implement PLR in a newer memory device.

Since the PLR operation is performed by memory 120, nonvolatile cells of nonvolatile memory 120 may be allocated for storing the PLR status bits during the design of nonvolatile memory 120. This may be advantages compared to systems that implement PLR using software executed by a processor external to nonvolatile memory 120 that may need to use user memory space, e.g., allocate space in the memory for headers to store the PLR bits for each block of memory. The space occupied by the header may reduce the storage area available for use by the operating system (O/S) or other software executed during operation of the system. In one embodiment, all memory space of the nonvolatile memory is available since no user memory space is used for the PLR status bits, but rather the cells needed for the PLR status bits may be pre-allocated during the design and manufacture of the memory.

As discussed above, in one embodiment, the present invention provides a method to set at least one power loss recovery (PLR) status bit in response to the writing or erasing of a plurality of nonvolatile memory cells (e.g., colony 153) of a nonvolatile memory (e.g., memory 120), wherein the at least one PLR status bit indicates whether the writing or erasing of the plurality of memory cells was interrupted by a loss of power that may result in corrupted or invalid data stored in the plurality of nonvolatile memory cells and wherein the setting of the at least one PLR status bit is performed by the nonvolatile memory. The PLR status bit(s) may be used to determine if the plurality of memory cells includes invalid or corrupt data due to an unexpected loss of power.

Further, in one embodiment, the present invention provides a nonvolatile memory comprising a control circuit (e.g., controller 170) to set at least one power loss recovery (PLR) status bit in response to a write operation or an erase operation to a plurality of nonvolatile memory cells (e.g., colony 153) of a nonvolatile memory (e.g., 120), wherein the at least one PLR status bit indicates whether the write or erase operation was interrupted by a loss of power and wherein the at least one PLR status bit is set by the nonvolatile memory.

Turning to FIG. 6, shown is a block diagram illustrating a wireless device 600 in accordance with an embodiment of the present invention. In one embodiment, wireless device 600 may use the methods discussed above and may include computing system 100 (FIG. 1).

As is shown in FIG. 2, wireless device 600 may include an antenna 620 coupled to a processor (e.g., processor 110) of system 100 via a wireless interface 630. In various embodiments, antenna 620 may be a dipole antenna, helical antenna or another antenna adapted to wirelessly communicate information. Wireless interface 630 may be adapted to process radio frequency (RF) and baseband signals using wireless protocols and may include a wireless transceiver.

Wireless device 600 may be a personal digital assistant (PDA), a laptop or portable computer with wireless capability, a web tablet, a wireless telephone (e.g., cordless or cellular phone), a pager, an instant messaging device, a digital music player, a digital camera, or other devices that may be adapted to transmit and/or receive information wirelessly. Wireless device 600 may be used in any of the following systems: a wireless personal area network (WPAN) system, a wireless local area network (WLAN) system, a wireless metropolitan area network (WMAN) system, or a wireless wide area network (WWAN) system such as, for example, a cellular system.

An example of a WLAN system includes a system substantially based on an Industrial Electrical and Electronics Engineers (IEEE) 802.11 standard. An example of a WMAN system includes a system substantially based on an Industrial Electrical and Electronics Engineers (IEEE) 802.16 standard. An example of a WPAN system includes a system substantially based on the Bluetooth™ standard (Bluetooth is a registered trademark of the Bluetooth Special Interest Group). Another example of a WPAN system includes a system substantially based on an Industrial Electrical and Electronics Engineers (IEEE) 802.15 standard such as, for example, the IEEE 802.15.3a specification using ultrawideband (UWB) technology.

Examples of cellular systems include: Code Division Multiple Access (CDMA) cellular radiotelephone communication systems, Global System for Mobile Communications (GSM) cellular radiotelephone systems, Enhanced data for GSM Evolution (EDGE) systems, North American Digital Cellular (NADC) cellular radiotelephone systems, Time Division Multiple Access (TDMA) systems, Extended-TDMA (E-TDMA) cellular radiotelephone systems, GPRS, third generation (3G) systems like Wide-band CDMA (WCDMA), CDMA-2000, Universal Mobile Telecommunications System (UMTS), or the like.

Although computing system 100 is illustrated as being used in a wireless device in one embodiment, this is not a limitation of the present invention. In alternate embodiments system 100 may be used in non-wireless devices such as, for example, a server, a desktop, or an embedded device not adapted to wirelessly communicate information.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. A method, comprising:
setting at least one power loss recovery (PLR) status bit in response to the writing to or erasing of a plurality of nonvolatile memory cells of a nonvolatile memory, wherein the at least one PLR status bit indicates whether the writing to or erasing of the plurality of memory cells was interrupted by a loss of power and wherein the setting of the at least one PLR status bit is performed by the nonvolatile memory.

2. The method of claim 1, wherein setting includes setting the at least one PLR status bit after completing the writing or erasing of the plurality of memory cells.

3. The method of claim 1, wherein the writing to the plurality of memory cells includes a write operation to write data to the plurality of memory cells and wherein setting includes setting only one PLR status bit for the write operation.

4. The method of claim 1, wherein the writing to the plurality of memory cells includes a write operation to write data to the plurality of memory cells and wherein setting includes setting a first PLR status bit and a second PLR status bit, wherein the first PLR status bit is set prior to beginning the write operation and wherein the second PLR status bit is set after the write operation is completed.

5. The method of claim 1, wherein the erasing of the plurality of memory cells includes an erase operation to erase the plurality of memory cells, wherein setting includes setting a first PLR status bit and a second PLR status bit, and wherein the first PLR status bit is set prior to beginning the erase operation and wherein the second PLR status bit is set after the erase operation is completed.

6. The method of claim 1, wherein setting the at least one PLR status bit includes storing the at least one PLR status bit in a PLR status cell linked to the plurality of nonvolatile memory cells and wherein the PLR status cell is a nonvolatile memory cell of the nonvolatile memory.

7. The method of claim 1, wherein setting the at least one PLR status bit includes storing two PLR status bits using two PLR status cells that correspond to the plurality of nonvolatile memory cells and wherein the two PLR status cells are nonvolatile memory cells of the nonvolatile memory.

8. The method of claim 1 further comprising determining whether the plurality of memory cells includes invalid data based on the at least one PLR status bit.

9. The method of claim 8, wherein the determining is performed upon power-up of the non-volatile memory or prior to reading information stored in plurality of nonvolatile memory cells and further comprising sending an address of the plurality of memory cells to a device external to the nonvolatile memory if the plurality of memory cells includes invalid data.

10. The method of claim 8, wherein the determining is performed by the nonvolatile memory and wherein determining comprises:
determining whether programmed data is stored in the plurality of nonvolatile memory cells; and
determining whether the at least one PLR status bit is set.

11. A nonvolatile memory, comprising:
a control circuit to set at least one power loss recovery (PLR) status bit in response to a write operation or an erase operation to a plurality of nonvolatile memory cells of the nonvolatile memory, wherein the at least one PLR status bit indicates whether the write operation or the erase operation was interrupted by a loss of power and wherein the at least one PLR status bit is set by the control circuit of the nonvolatile memory.

12. The nonvolatile memory of claim 11, wherein the nonvolatile memory is a flash electrically erasable programmable read-only memory (EEPROM) and the flash EEPROM includes at least one status cell to store the at least one PLR status bit, wherein status cell is a flash memory cell of the flash EEPROM.

13. The nonvolatile memory of claim 11, wherein the control circuit includes circuitry to write to, read from, or erase the plurality of nonvolatile memory cells.

14. The nonvolatile memory of claim 11, wherein the nonvolatile memory includes a plurality of memory blocks, wherein each block of the plurality of memory blocks includes a plurality of colonies, wherein each colony of the plurality of colonies includes a plurality of memory cells and wherein the control circuit sets the at least one PLR status bit after the completion of the write operation to the plurality of nonvolatile memory cells.

15. The nonvolatile memory of claim 14, wherein a colony of the plurality of colonies is at least about 512 bytes in size and wherein a block of the plurality of memory blocks is at least about 64 kilobytes in size.

16. The nonvolatile memory of claim 11, wherein control circuit includes circuitry to determine whether the plurality of memory cells includes invalid data based on the at least one PLR status bit and to send an address of the plurality of memory cells to a device external to the nonvolatile memory if the plurality of memory cells includes invalid data.

17. The nonvolatile memory of claim 11, wherein the control circuit is coupled to a memory array of the nonvolatile memory.

18. The nonvolatile memory of claim 11, wherein the nonvolatile memory is a ferroelectric random access memory (FRAM), a magnetic random access memory (MRAM), or a disk memory.

19. A system, comprising:
a processor;
an antenna coupled to the processor; and
a flash electrically erasable programmable read-only memory (EEPROM) coupled to the processor, wherein the flash EEPROM comprises a control circuit to set at least one power loss recovery (PLR) status bit in response to a write operation or an erase operation to a plurality of memory cells of the flash EEPROM, wherein the at least one PLR status bit indicates whether the write operation or the erase operation was interrupted by a loss of power and wherein the at least one PLR status bit is set by the control circuit of the flash EEPROM.

20. The system of claim 19, wherein the system is a wireless phone.

21. The system of claim 19, wherein control circuit includes circuitry to determine whether the plurality of memory cells includes invalid data based on the at least one PLR status bit and to send an address of the plurality of memory cells to the processor from the flash EEPROM if the plurality of memory cells includes invalid data.

22. A method, comprising:
setting at least one power loss recovery (PLR) status bit in response to the writing to a plurality of nonvolatile memory cells of a nonvolatile memory, wherein the at least one PLR status bit indicates whether the writing to the plurality of memory cells was interrupted by a loss of power and wherein the setting of the at least one PLR status bit is performed by the nonvolatile memory; and
receiving an address of the plurality of nonvolatile memory cells from the nonvolatile memory.

23. The method of claim 22, further comprising determining whether the plurality of memory cells includes invalid data based on the PLR status bit.
